(19) United States
(12) Patent Application Publication
(10) Pub. No.: US 2023/0204392 A1
(43) Pub. Date: Jun. 29, 2023

(54) APPARATUS AND METHOD FOR DETECTING A FAILURE OF A MOTOR DRIVE CIRCUIT

(71) Applicant: HYUNDAI AUTOEVER CORP., Seoul (KR)

(72) Inventor: Ji-Su Seo, Seoul (KR)

(73) Assignee: HYUNDAI AUTOEVER CORP., Seoul (KR)

(21) Appl. No.: 18/080,197

(22) Filed: Dec. 13, 2022

(30) Foreign Application Priority Data
Dec. 27, 2021 (KR) 10-2021-0188669

(51) Int. Cl. G01D 5/244

(52) U.S. Cl. CPC G01D 5/24457

(57) ABSTRACT

An apparatus for detecting a failure of a motor drive circuit includes an encoder for detecting rotation information of a motor. The apparatus also includes an interface configured to transmit rotation information detected by the encoder to a processor. The apparatus also includes the processor configured to control the motor based on the rotation information of the motor and configured to receive through the interface and detecting a failure of the interface.

### CROSS-REFERENCE TO RELATED APPLICATION

This application claims priority from and the benefit to Korean Patent Application No. 10-2021-0188669, filed on Dec. 27, 2021, which is hereby incorporated by reference for all purposes herein.

### FIELD

The present disclosure relates to an apparatus and a method for detecting a failure of a motor drive circuit, and more particularly, to detect a failure of a motor drive circuit including an encoder.

### BACKGROUND

The statements in this section merely provide background information related to the present disclosure and may not constitute prior art.

Recently, vehicles have been increasingly equipped with electric motors (for example, permanent magnet synchronous motors (PMSM) (hereinafter, simply described as motors) that use batteries as power sources, and a controller is installed to control motors.

A controller mounted on this type of an electric vehicle controls a motor drive circuit to drive a motor and controls the electric vehicle by various input signals.

Accordingly, for stable driving of the electric vehicle, the controller checks whether the motor drive circuit is abnormal and the controller warns a user when there is an abnormality in the motor drive circuit to respond to the abnormality.

### SUMMARY

According to an aspect of the present disclosure, an object of the present disclosure is to solve the above problem by providing an apparatus and a method for detecting a failure of a motor drive circuit including an encoder.

In an embodiment, an apparatus for detecting a failure of a motor drive circuit according to an aspect of the present disclosure includes an encoder configured to detect rotation information of a motor. The apparatus also includes an interface configured to transmit rotation information detected by the encoder to a processor.

The apparatus also includes the processor configured to control the motor based on the rotation information of the motor received through the interface and configured to detect a failure of the encoder and the interface based on the rotation information.

In an embodiment, the rotation information of the motor may include first and second signals indicating the rotation direction information and may include a pulse width modulation (PWM) signal indicating operation status (angle) information.

In an embodiment, the interface may include a first series resistor connecting a first signal line configured to output a first signal of the encoder to a designated terminal of the processor. The interface may further include a second series resistor connecting a second signal line configured to output a second signal of the encoder to the designated terminal of the processor. The interface may further include a third series resistor and a pull-up circuit connecting a signal line configured to output a PWM signal of the encoder to the designated terminal of the processor.

In an embodiment, the processor may detect a failure of the encoder itself and electrical failures occurring in first and second signal lines of the interface and a PWM signal line.

In an embodiment, in order to detect the failure in the encoder itself, the processor may determine that there is a possibility that the encoder is in an abnormal state, when there is no change in the state of the first and second signals regardless of a rotation direction of the motor. Alternatively, the processor may determine that there is a possibility that the encoder is in an abnormal state when the state of the first and second signals does not change in a specified order and changes in an unspecified order according to the rotation direction of the motor.

In an embodiment, if it is determined that there is a possibility that the encoder is in the abnormal state, the processor may perform an Invalid Count. When the Invalid Count is greater than or equal to a specified first reference count for a specified reference time, the processor resets an Invalid Counter. When the Invalid Count increases above the specified second reference count for the specified reference time, the processor is determined to be a failure of the encoder.

In an embodiment, when the PWM signal is not output for a specified first time and a high level state is kept maintained, the processor may determine that a “SBOP (Shot to Battery or Open)” has occurred in the PWM signal line. After a specified debounce time has elapsed, the processor determines that a final SBOP is fault and blocks a motor output end.

In an embodiment, in a case where the PWM signal is not output for the specified first time and a low level state is kept maintained, the processor may determine that a “SG (Shot to Ground)” has occurred in the PWM signal line. After the specified debounce time has elapsed, the processor determines that a final SG is fault and blocks the motor output end.

In an embodiment, when there is no abnormality in the PWM signal of the encoder, the processor may forcibly drive the motor in a first direction (CW direction) and calculate a rotation angle of the motor by the PWM signal and a rotation angle of the motor calculated by first and second signals of the encoder to check an angle difference. The processor may forcibly drive the motor in a second direction (CCW direction) and then may calculate the rotation angle of the motor by the PWM signal and the rotation angle of the motor calculated by the first and second signals of the encoder to check the angle difference. When the angle difference identified in any one of the first direction (CW direction) and the second direction (CCW direction) is greater than a specified failure reference angle, the processor may determine that an electrical failure occurs in the first and second signal lines of the interface.

In another embodiment, a method for detecting a failure of a motor drive circuit according to another aspect of the present disclosure may include detecting, by an encoder, rotation information of a motor. The method may further include receiving, by a processor, rotation information detected by the encoder through an interface. The method may further include controlling, by the processor, the motor based on the rotation information of the motor received through the interface. The method may further include detecting, by the processor, a failure of the encoder and the interface based on the rotation information.

In an embodiment, the rotation information of the motor may include first and second signals indicating rotation direction information and may include a PWM signal indicating operation state information.

In an embodiment, the detecting of a failure of the encoder and the interface, the processor detects a failure of the encoder itself and an electrical failure occurring in first and second signal lines and the PWM signal line of the interface.

In an embodiment, in order to detect a failure that occurs in the encoder itself, the processor may determine that there is a possibility that the encoder is in an abnormal state, when the state of the first and second signals does not change regardless of the direction of rotation of the motor. Alternatively, the processor may determine that there is a possibility that the encoder is in an abnormal state, when the state of the first and second signals does not change in the specified order and changes in the unspecified order according to a rotation direction of the motor.

The present disclosure may enable detection of a failure of a motor drive circuit including an encoder and thus may alert a user to respond to the failure when the motor drive circuit has a failure.

### BRIEF DESCRIPTION OF THE DRAWINGS

In order that the disclosure may be well understood, there are now described various forms thereof, given by way of example, reference being made to the accompanying drawings, in which:

FIG. 1 is a diagram illustrating a schematic configuration of a motor drive circuit according to an embodiment of the present disclosure;

FIG. 2 is a diagram illustrating a more detailed configuration of the motor drive circuit in FIG. 1;

FIGS. 3A and 3B are diagrams illustrating a rotation information signal waveform of a motor output from an encoder in FIG. 1;

FIGS. 4 and 5 are diagrams illustrating a method of detecting an electrical failure occurring in a pulse width modulation (PWM) signal line of an interface in FIG. 2;

FIG. 6 is a flowchart illustrating a method of detecting an electrical failure occurring in signal lines A and B of an interface in FIG. 2; and

FIG. 7 is a diagram illustrating a method of detecting an electrical failure occurring in signal lines A and B of an interface in FIG. 6.

### DETAILED DESCRIPTION

Hereinafter, embodiments of the present disclosure are described in detail with reference to the accompanying drawings so that a person of ordinary skill in the art may easily implement the present disclosure. However, the present disclosure may be implemented in several different forms and is not limited to the embodiments described herein. In addition, in order to clearly explain the present disclosure in the drawings, parts unrelated to the description have been omitted, and similar reference numbers refer to similar parts throughout the specification.

Throughout the present specification, the term “include” means that a constituent element may further include any other constituent element. The term “include” does not exclude any other constituent element, unless otherwise particularly described.

The implementation described above in the present specification may be performed by, for example, a method or a process, an apparatus, a software program, a data stream, or a signal. Although the features are discussed only in the context of single form implementation (for example, the features are discussed only as a method), the discussed features may be implemented even as another form (for example, apparatus or program). The apparatus may be implemented as a proper hardware, software, and firmware. The method may be implemented as, for example, an apparatus, such as a processor. The processor may refer to a processing apparatus including a computer, a microprocessor, an integrated circuit, or a programmable logic apparatus. The processor also includes a communication apparatus, such as a computer, a cellular phone, a portable/personal digital assistant (PDA), and other devices, which facilitate information communication between end users. When a component, device, element, or the like of the present disclosure is described as having a purpose or performing an operation, function, or the like, the component, device, or element should be considered herein as being “configured to” meet that purpose or to perform that operation or function.

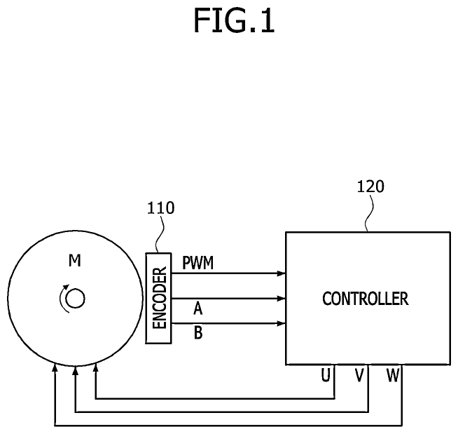

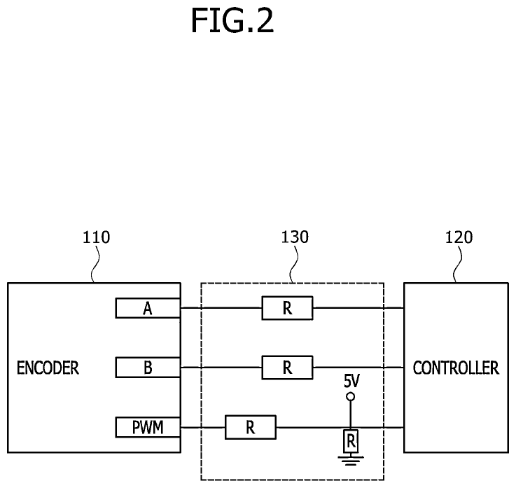

FIG. 1 is a diagram illustrating a schematic configuration of a motor drive circuit according to an embodiment of the present disclosure, and FIG. 2 is a diagram illustrating a more detailed configuration of the motor drive circuit in FIG. 1.

As illustrated in FIG. 1, a motor drive circuit according to an embodiment includes a motor M, an encoder (or encoder sensor) 110 that detects rotation information of a motor, and a processor 120 that controls the motor M based on rotation information (for example, pulse width modulation (PWM), A, B) detected by the encoder 110.

Referring to FIG. 2, an interface 130 is included between the encoder 110 and the processor 120.

The processor 120 outputs signals for controlling phase U, V, and W to control the motor M (for example, permanent magnet synchronous motor (PMSM) motor), and the encoder 110 transmits rotation information (for example, rotation direction information A and B) and operation state (angle) information (for example, PWM of the motor M) to the processor 120.

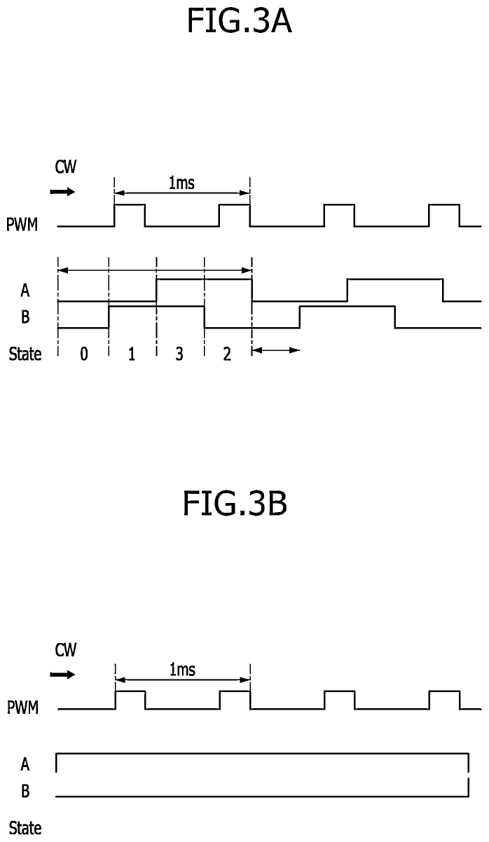

FIGS. 3A and 3B are diagrams illustrating a rotation information signal waveform of a motor output from an encoder in FIG. 1, FIG. 3A is a view illustrating a rotation information signal waveform output from the encoder when the motor M rotates in a first direction (CW direction), and FIG. 3B is a view illustrating a rotation information signal waveform output from the encoder when the motor M stops.

Referring to FIG. 3A, when the motor M rotates in the first direction (CW direction), changes in the state (STATE) of the A and B signals are in the order of 0→1→3→2. When the motor M rotates in a second direction (CCW direction), changes in the state (STATE) of the A and B signals are in the order of 0→2→3→1.

Referring to FIG. 3B, when the motor M does not rotate, the A and B signals continue to remain high or low.

Referring back to FIG. 2, the interface 130 includes a first series resistor R connecting a signal line outputting an A signal of the encoder 110 to a designated terminal of the processor 120. The interface 130 also includes a second series resistor R connecting a signal line outputting a B signal of the encoder 110 to the designated terminal of the processor 120. The interface 130 also includes a third series resistor R and a pull-up circuit connecting a signal line outputting a PWM signal of the encoder 110 to the designated terminal of the processor 120.

The motor drive circuit illustrated in FIG. 2 may cause a failure (hereinafter, referred to as a GEN failure) in the encoder 110 itself or an electrical failure (i.e., short or open) in the interface 130.

Hereinafter, a method of detecting a failure (abnormal) that may occur in the motor drive circuit is described by the processor 120.

First, the processor 120 may detect a failure (hereinafter, referred to as a GEN failure) occurring in the encoder 110 itself.

For example, if the state (STATE) change of A and B signals becomes 0→1→3→2 in order when the motor M rotates in the first direction (CW direction), and the state (STATE) of A and B signals becomes 0→2→3→1 in order when the motor M rotates in the second direction (CCW direction), the encoder 110 is determined to be in a normal state.

However, in a case where there is no change in the state (STATE) of the A and B signals regardless of a rotation direction of the motor M (for example, 0→0→0→0), or in a case where the status (STATE) of the A and B signals does not change in the specified order according to the direction of rotation of the motor, but changes in the unspecified order (for example, 0→3→0→1), the processor 120 determines that there is a possibility that the encoder 110 is in an abnormal state and performs an invalid count.

Further, in a case where the Invalid Count is greater than or equal to the specified first reference count (for example, 10 count) for a specified reference time (for example, 5 ms), an Invalid Counter is reset. In a case where Invalid Count increases to a specified second reference count (for example, 1000 count) or more for a specified reference time (for example, 5 ms), the processor 120 determines that the encoder 110 is failed (abnormal).

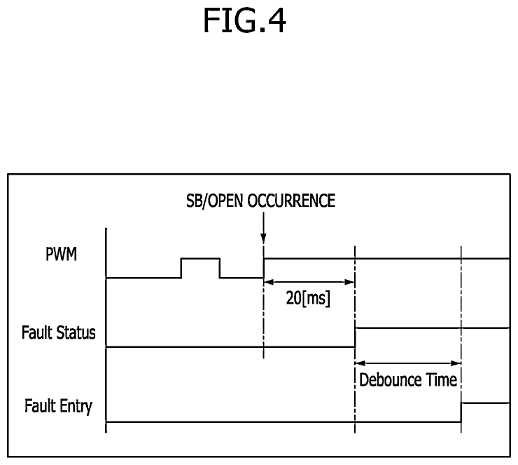

In addition, the processor 120 may detect an electrical failure (i.e., short or open) occurring in the PWM signal line of the interface 130 (refer to FIG. 4).

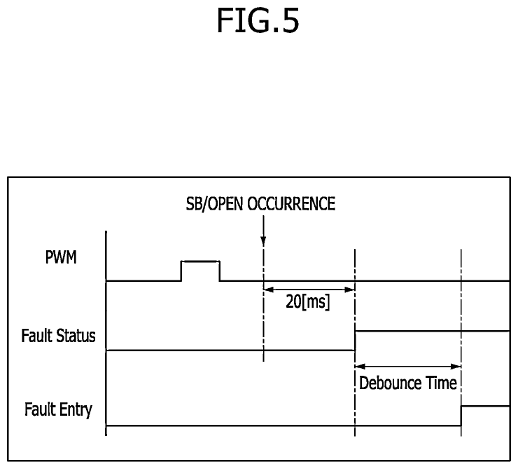

FIGS. 4 and 5 are views illustrating a method of detecting an electrical failure occurring in a PWM signal line of an interface in FIG. 2.

As illustrated in FIGS. 3A and 3B, the PWM signal must periodically output a pulse signal (for example, 1 ms interval).

However, as illustrated in FIG. 4, in a case where a PWM pulse signal is not output for a specified first time (for example, 20 ms) and a constant level state (for example, high level state, low level state) is kept maintained, the processor 120 determines that an electrical fault (i.e., short or open) is occurred in a PWM signal line (Fault Status signal output) and outputs a final fault signal (Fault Entry output) after a specified debounce time (for example, 400 ms) is elapsed. In other words, it is determined that a PWM line of the encoder 110 is a “SBOP (Shot to Battery or Open)” fault and a motor output terminal is blocked.

For example, in a case where the PWM pulse signal is not output for the specified first time (for example, 20 ms) and the high level state is kept maintained, it is determined that the PWM signal line is in a short to battery or open state (refer to FIG. 4).

Meanwhile, as illustrated in FIG. 5, in a case where the PWM signal is not output for the specified first time (for example, 20 ms) and the constant level state (for example, high level state, low level state) is kept maintained, the processor 120 determines that the electrical fault (i.e., short or open) is occurred in the PWM signal line (Fault Status signal output) and outputs the final fault signal after the specified debounce time (for example, 400 ms) is elapsed (Fault Entry output). In other words, it is determined that the PWM signal line of the encoder 110 is a “SG (shot to ground)” failure and the motor output terminal is blocked.

For example, in a case where the PWM signal is not output for the specified first time (for example, 20 ms), and the low level state is kept maintained, it is determined that the PWM signal line is in a short to ground state (refer to FIG. 5).

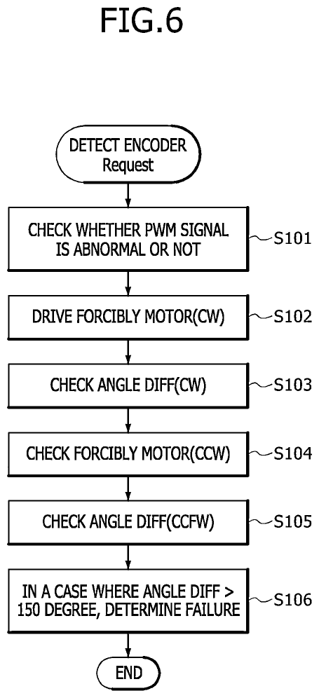

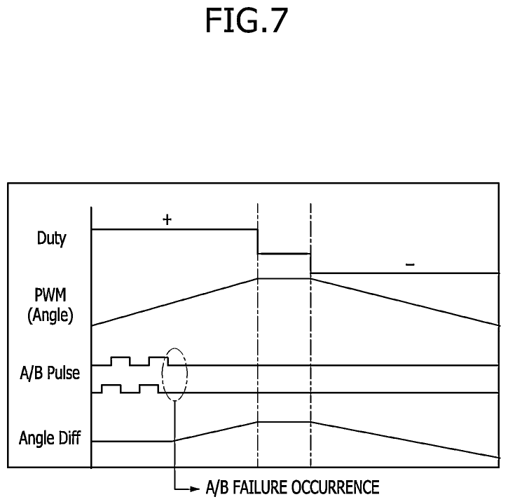

FIG. 6 is a flowchart illustrating a method of detecting an electrical failure occurring in signal lines A and B of an interface in FIG. 2, and FIG. 7 is a diagram illustrating a method of detecting an electrical failure occurring in signal lines A and B of an interface in FIG. 6.

Referring to FIGS. 6 and 7, the processor 120 checks whether the PWM signal of the encoder 110 is abnormal or not (S101). Then assuming that there is no abnormality in the PWM signal, the processor 120 forcibly drives the motor M in a first direction (CW direction) (S102). The processor 120 checks an angle difference (Angle Diff) between the rotation angle of the motor by the PWM signal and the rotation angle of the motor calculated by the A and B signals of the encoder 110 (S103).

In addition, the processor 120 forcibly drives the motor M in a second direction (CCW direction) (S104) and checks the angle difference between the rotation angle of the motor by the PWM signal and the rotation angle of the motor calculated by the A and B signals of the encoder 110 (S105).

Further, in a case where an angle difference (Angle Diff) identified in either the first direction (CW direction) or the second direction (CCW direction) is greater than a specified failure reference angle (for example, 150 degrees), the processor 120 determines that an electrical failure (for example, SB, SG, OP) has occurred in the A, B signal lines of the interface 130 (S106).

For example, referring to FIG. 7, it may be seen that there is no angle difference (Angle Diff) before the failure occurred in the A/B signal line. However, after the failure in the A/B signal line, the angle difference (Angle Diff) gradually increases. Accordingly, in a case where the angle difference (Angle Diff) identified in either the first direction (CW direction) or the second direction (CCW direction) is greater than the specified failure reference angle (for example, 150 degrees), the processor 120 determines that the electrical failure (for example, SB, SG, OP) occurred in the signal line of the interface 130.

As described above, since the present embodiment enables detection of a failure of a motor drive circuit including an encoder, when an abnormality (failure) is occurred in the motor drive circuit, there is an effect of warning a user to respond to the abnormality (failure).

Although the embodiment of the present disclosure has been described in detail, a scope of the present disclosure is not limited thereto, and various modifications and improvements of those having ordinary skill in the art using a basic concept of the present disclosure defined in the following claims also belong to a scope of the present disclosure.

What is claimed is:

1. An apparatus for detecting a failure of a motor drive circuit, the apparatus comprising:
an encoder configured to detect rotation information of a motor; and
an interface configured to transmit rotation information detected by the encoder to a processor,
wherein the processor is configured to control the motor based on the rotation information of the motor received through the interface and configured to detect a failure of the encoder and the interface based on the rotation information.

2. The apparatus of claim 1,
wherein the rotation information of the motor comprises:
first and second signals indicating the rotation direction information; and
a pulse width modulation (PWM) signal indicating operation status (angle) information.

3. The apparatus of claim 1,
wherein the interface comprises:
a first series resistor connecting a first signal line configured to output a first signal of the encoder to a designated terminal of the processor;
a second series resistor connecting a second signal line configured to output a second signal of the encoder to the designated terminal of the processor; and
a third series resistor and a pull-up circuit connecting a signal line configured to output a PWM signal of the encoder to the designated terminal of the processor.

4. The apparatus of claim 1,
wherein the processor is further configured to detect a failure of the encoder itself and electrical failures occurring in first and second signal lines of the interface and a pulse width modulation (PWM) signal line.

5. The apparatus of claim 4,
wherein in order to detect the failure in the encoder itself, the processor determines that there is a possibility that the encoder is in an abnormal state, when there is no change in the state of the first and second signals regardless of a rotation direction of the motor, or when the state of the first and second signals does not change in a specified order and changes in an unspecified order according to the rotation direction of the motor.

6. The apparatus of claim 5,
wherein when it is determined that there is a possibility that the encoder is in the abnormal state, the processor performs an Invalid Count,
wherein when the Invalid Count is greater than or equal to a specified first reference count for a specified reference time, the processor resets an Invalid Counter, and
wherein when the Invalid Count increases above a specified second reference count for the specified reference time, the processor determines the failure of the encoder.

7. The apparatus of claim 4,
wherein when the PWM signal is not output for a specified first time and a high level state is kept maintained, the processor determines that a “SBOP (Shot to Battery or Open)” has occurred in the PWM signal line, and
wherein after a specified debounce time has elapsed, the processor determines that a final SBOP is fault and blocks a motor output end.

8. The apparatus of claim 4,
wherein when the PWM signal is not output for the specified first time and a low level state is kept maintained, the processor determines that a “SG (Shot to Ground)” has occurred in the PWM signal line, and
wherein after the specified debounce time has elapsed, the processor determines that a final SG is fault and blocks the motor output end.

9. The apparatus of claim 4,
wherein when there is no abnormality in the PWM signal of the encoder, the processor forcibly drives the motor in a first direction and calculates a rotation angle of the motor by the PWM signal and a rotation angle of the motor calculated by first and second signals of the encoder to check an angle difference,
wherein the processor forcibly drives the motor in a second direction and then calculates the rotation angle of the motor by the PWM signal and the rotation angle of the motor calculated by the first and second signals of the encoder to check the angle difference, and
wherein when the angle difference identified in any one of the first direction and the second direction is greater than a specified failure reference angle, the processor determines that an electrical failure occurs in the first and second signal lines of the interface.

10. A method for detecting a failure of a motor drive circuit, the method comprising:
detecting, by an encoder, rotation information of a motor;
receiving, by a processor, rotation information detected by the encoder through an interface;
controlling, by the processor, the motor based on the rotation information of the motor received through the interface; and
detecting, by the processor, a failure of the encoder and the interface based on the rotation information.

11. The method of claim 10,
wherein the rotation information of the motor comprises:
a first signal and a second signal indicating rotation direction information; and
a pulse width modulation (PWM) signal indicating operation state information.

12. The method of claim 10,
wherein in detecting the failure of the encoder and the interface, the processor detects a failure of the encoder itself and an electrical failure occurring in first and second signal lines and the PWM signal line of the interface.

13. The method of claim 10,
wherein in order to detect a failure that occurs in the encoder itself, the processor determines that there is a possibility that the encoder is in an abnormal state, when the state of the first and second signals does not change regardless of the direction of rotation of the motor, or when the state of the first and second signals does not change in a specified order and changes in an unspecified order according to a rotation direction of the motor.
